(19) United States
(12) Patent Application Publication
(10) Pub. No.: US 2023/0089399 A1
(43) Pub. Date: Mar. 23, 2023

(54) SEMICONDUCTOR DEVICE AND SEMICONDUCTOR PACKAGE INCLUDING THE SAME

(71) Applicant: SAMSUNG ELECTRONICS CO., LTD., Suwon-si (KR)

(72) Inventors: Solji SONG, Suwon-si (KR); Junyun Kweon, Cheonan-si (KR); Jumyong Park, Cheonan-si (KR); Dongjoon Oh, Suwon-si (KR); Chungsun Lee, Asan-si (KR); Hyunsu Hwang, Siheung-si (KR)

(73) Assignee: SAMSUNG ELECTRONICS CO., LTD., Suwon-si (KR)

(21) Appl. No.: 17/719,721

(22) Filed: Apr. 13, 2022

(30) Foreign Application Priority Data
Sep. 17, 2021 (KR) 10-2021-0124638

(51) Int. Cl. H01L 23/528; H01L 23/532; H01L 21/78; H01L 23/498; H01L 25/00; H01L 25/065; H01L 23/00; H01L 23/16

(52) U.S. Cl. CPC H01L 23/528; H01L 23/5329; H01L 21/78; H01L 23/49827; H01L 25/50; H01L 25/0657; H01L 24/16; H01L 23/16; H01L 2924/1015; H01L 2224/16145

(57) ABSTRACT

A semiconductor device includes a substrate, an insulating layer on a bottom surface of the substrate, a portion of a top surface of the insulating layer that faces the substrate being exposed outside a side surface of the substrate, a through via penetrating the substrate, an interconnection structure in the insulating layer, and a dummy pattern on the portion of the top surface of the insulating layer that is exposed by the substrate.

### CROSS-REFERENCE TO RELATED APPLICATIONS

This U.S. non-provisional patent application claims priority under 35 U.S.C. § 119 to Korean Patent Application No. 10-2021-0124638, filed on Sep. 17, 2021, in the Korean Intellectual Property Office, the entire contents of which are hereby incorporated by reference.

### BACKGROUND

The present disclosure relates to a semiconductor device and a semiconductor package including the same, and in particular, to a semiconductor device with improved reliability and a semiconductor package including the same.

With the recent advance in the electronics industry, demand for high-performance, high-speed and compact electronic components are increasing. To meet this demand, packaging technologies of mounting a plurality of semiconductor chips in a single package are being developed.

Recently, demand for portable electronic devices has been rapidly increasing in the market, and thus, it is necessary to reduce sizes and weights of electronic components constituting the portable electronic devices. For this, it is necessary to develop packaging technologies of reducing a size and a weight of each component and of integrating a plurality of individual components in a single package. In particular, for a semiconductor package used to process high frequency signals, it is necessary not only to reduce a size of a product but also to realize good electrical characteristics.

### SUMMARY

It is an aspect to provide a semiconductor device with improved reliability.

It is another aspect to provide a semiconductor package including a semiconductor device with improved reliability.

According to an aspect of one or more example embodiments, there is provided a semiconductor device comprising a substrate; an insulating layer on a bottom surface of the substrate, a portion of a top surface of the insulating layer that faces the substrate being exposed outside a side surface of the substrate; a through via penetrating the substrate; an interconnection structure in the insulating layer; and a dummy pattern on the portion of the top surface of the insulating layer that is exposed by the substrate.

According to another aspect of one or more example embodiments, there is provided a semiconductor device comprising a substrate; an insulating layer on a bottom surface of the substrate; a through via penetrating the substrate; an interconnection structure in the insulating layer; and a first connection pad adjacent to a bottom surface of the insulating layer, wherein a portion of a top surface of the insulating layer is outside a side surface of the substrate, and wherein an angle between the bottom surface and a side surface of the insulating layer is an acute angle.

According to yet another aspect of one or more example embodiments, there is provided a semiconductor package comprising a package substrate; a first semiconductor chip on the package substrate; and a plurality of outer terminals on a bottom surface of the package substrate. The first semiconductor chip comprises a substrate; an insulating layer on a bottom surface of the substrate; a through via penetrating the substrate; an interconnection structure in the insulating layer, the interconnection structure comprising a conductive via penetrating a portion of the insulating layer, and a conductive pattern electrically connected to the conductive via; a stepwise portion, which is provided by a portion of the insulating layer protruding outward from a side surface of the substrate; and a dummy pattern disposed on the stepwise portion.

### BRIEF DESCRIPTION OF THE DRAWINGS

FIG. 1 is a plan view illustrating a semiconductor package including a semiconductor device according to example embodiments;

FIG. 2 is a sectional view, which is taken along a line I-I′ of FIG. 1 to illustrate a semiconductor package including a semiconductor device according to example embodiments;

FIG. 3 is an enlarged sectional view illustrating a portion ‘A’ of FIG. 2;

FIG. 4 is a sectional view, which is taken along the line I-I′ of FIG. 1 to illustrate a semiconductor package including a semiconductor device according to example embodiments;

FIG. 5 is a sectional view, which is taken along the line I-I′ of FIG. 1 to illustrate a semiconductor package including a semiconductor device according to example embodiments;

FIG. 6 is a plan view illustrating a semiconductor package including a semiconductor device according to example embodiments;

FIG. 7 is a sectional view, which is taken along a line I-I′ of FIG. 6 to illustrate a semiconductor package including a semiconductor device according to example embodiments;

FIG. 8 is a sectional view, which is taken along a line I-I′ of FIG. 6 to illustrate a semiconductor package including a semiconductor device according to example embodiments;

FIGS. 9, 10, 11, 13, 15, and 16 are sectional views illustrating a method of fabricating of a semiconductor package including a semiconductor device according to example embodiments;

FIG. 12 is an enlarged sectional view illustrating a portion ‘B’ of FIG. 11; and

FIG. 14 is an enlarged sectional view illustrating a portion ‘C’ of FIG. 13.

### DETAILED DESCRIPTION

Example embodiments will now be described more fully with reference to the accompanying drawings, in which various example embodiments are shown.

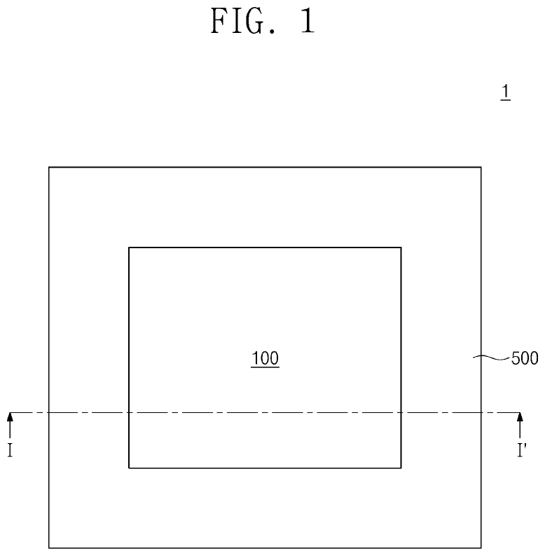

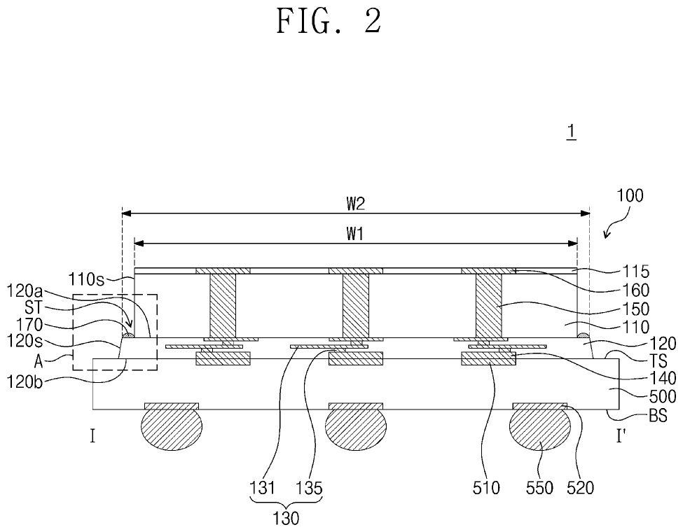

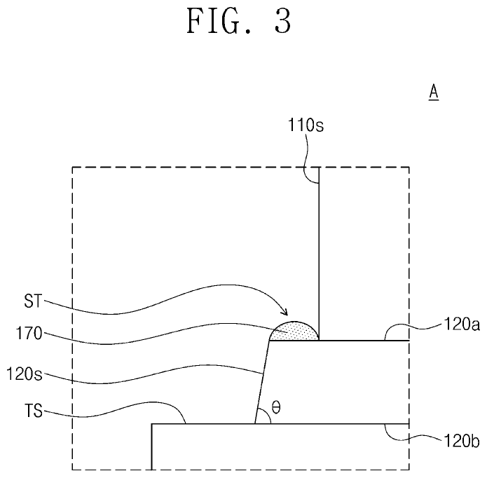

FIG. 1 is a plan view illustrating a semiconductor package including a semiconductor device according to example embodiments. FIG. 2 is a sectional view, which is taken along a line I-I′ of FIG. 1 to illustrate a semiconductor package including a semiconductor device according to example embodiments. FIG. 3 is an enlarged sectional view illustrating a portion ‘A’ of FIG. 2.

Referring to FIGS. 1, 2, and 3, a semiconductor package 1 may include a first semiconductor chip 100 and a package substrate 500.

The package substrate 500 may be for example a printed circuit board (PCB). The package substrate 500 may include a single insulating layer or a plurality of stacked insulating layers. The package substrate 500 may include package substrate pads 510 and terminal pads 520. The package substrate pads 510 may be adjacent to a top surface TS of the package substrate 500, and the terminal pads 520 may be adjacent to a bottom surface BS of the package substrate 500. The package substrate pads 510 may be exposed to the outside of the package substrate 500 near the top surface TS of the package substrate 500. The package substrate pads 510 and the terminal pads 520 may be electrically connected to each other through internal lines (not shown) in the package substrate 500. The package substrate pads 510 and the terminal pads 520 may be formed of or include at least one of conductive metal materials. The package substrate pads 510 and the terminal pads 520 may be formed of or include at least one of copper (Cu), aluminum (Al), tungsten (W), or titanium (Ti). In the present specification, the expression “two elements are electrically connected/coupled to each other” may mean that the elements are directly connected/coupled to each other or are indirectly connected/coupled to each other through another conductive element.

Outer terminals 550 may be provided on the bottom surface BS of the package substrate 500. The outer terminals 550 may be disposed on bottom surfaces of the terminal pads 520 and may be electrically connected to the terminal pads 520. The outer terminals 550 may be coupled to an external device. Accordingly, electrical signals from the outside may be transmitted to the package substrate pads 510 through the outer terminals 550. The outer terminal 550 may include at least one of, for example, solder balls, bumps, or pillars. The outer terminals 550 may include a conductive metal material. For example, the outer terminals 550 may be formed of or include at least one of tin (Sn), lead (Pb), silver (Ag), zinc (Zn), nickel (Ni), gold (Au), copper (Cu), aluminum (Al), or bismuth (Bi).

The first semiconductor chip 100 may be provided on the package substrate 500 and may be mounted on the top surface TS of the package substrate 500. The first semiconductor chip 100 may include a substrate 110 and an insulating layer 120. The first semiconductor chip 100 may be one of a memory chip, a logic chip, or combinations thereof. In the present specification, a semiconductor device may mean the first semiconductor chip 100.

The substrate 110 may be formed of or include at least one of semiconductor materials (e.g., silicon, germanium, or silicon germanium). As an example, the substrate 110 may be a chip level substrate. In some example embodiments, a side surface 110s of the substrate 110 may be substantially perpendicular to the top surface TS of the package substrate 500 (or top surface of the substrate 110).

The insulating layer 120 may be disposed on a bottom surface of the substrate 110. The insulating layer 120 may include an insulating material. For example, the insulating layer 120 may be formed of or include at least one of silicon oxide, silicon nitride, or silicon oxynitride. The insulating layer 120 may be composed of a single layer or may include a plurality of stacked layers. In some example embodiments, a side surface 120s of the insulating layer 120 may be inclined at an angle with respect to the top surface TS of the package substrate 500. For example, an angle (θ) between a bottom surface 120b of the insulating layer 120 and the side surface 120s of the insulating layer 120 may be an acute angle. The angle (θ) between the bottom and side surfaces 120b and 120s of the insulating layer 120 may be equal to or greater than 20° and may be smaller than 90°. As an example, a width of an upper portion of the insulating layer 120 may be smaller than a width of a lower portion of the insulating layer 120. The substrate 110 may be provided to expose a portion of a top surface 120a of the insulating layer 120. A width of the insulating layer 120 may increase as a distance from the bottom surface 120b of the insulating layer 120 decreases. The side surface 120s of the insulating layer 120 may protrude outward from the side surface 110s of the substrate 110. That is, the side surface 120s of the insulating layer 120 may be misaligned with the side surface 110s of the substrate 110. A width W1 of the substrate 110 may be smaller than a width W2 of the uppermost portion of the insulating layer 120 (i.e., the smallest width of the insulating layer 120). A difference of the width W2 of the uppermost portion of the insulating layer 120 and the width W1 of the substrate 110 may range from 10 μm to 130 μm. Since the side surface 120s of the insulating layer 120 is located outside the side surface 110s of the substrate 110, a stepwise portion ST may be formed between the top surface 120a of the insulating layer 120 and the side surface 110s of the substrate 110. In the present specification, a width of an element may mean a length of the element measured in a direction parallel to the top surface TS of the package substrate 500.

An interconnection structure 130 may be provided in the insulating layer 120. The interconnection structure 130 may include conductive patterns 131 and conductive vias 135. In example embodiments, a plurality of the interconnection structures 130 may be provided. The conductive vias 135 may be provided to penetrate a portion of the insulating layer 120 and may be electrically connected to the conductive patterns 131. The conductive patterns 131 and the conductive vias 135 may include a conductive metal material. For example, the conductive patterns 131 and the conductive vias 135 may be formed of or include at least one of copper (Cu), aluminum (Al), tungsten (W), or titanium (Ti). The insulating layer 120 may cover the conductive patterns 131 and the conductive vias 135.

First connection pads 140 may be provided in the insulating layer 120. The first connection pads 140 may be disposed adjacent to the bottom surface 120b of the insulating layer 120. The first connection pads 140 may be electrically connected to the interconnection structures 130. Each of the first connection pads 140 may be electrically connected to a corresponding one of the conductive vias 135. The first connection pads 140 may include a conductive metal material. For example, the first connection pads 140 may be formed of or include at least one of copper (Cu), aluminum (Al), tungsten (W), or titanium (Ti). In some embodiments, the first connection pads 140 may correspond in number and placement to the package substrate pads 510 of the package substrate 500 such that the each of the first connection pads 140 may be electrically connected to the package substrate pads 510 of the package substrate 500.

A through via 150 may be provided in the substrate 110. The through via 150 may be provided to penetrate the substrate 110. The through via 150 may be electrically connected to the interconnection structure 130. In example embodiments, a plurality of the through vias 150 may be provided. The through via 150 may include a conductive metal material. For example, the through via 150 may be formed of or include at least one of copper (Cu), aluminum (Al), tungsten (W), or titanium (Ti). Although not shown, an insulating layer and/or a barrier layer may be further interposed between the through via 150 and the substrate 110.

A pad insulating layer 115 may be provided on the top surface of the substrate 110. The pad insulating layer 115 may include an insulating material. For example, the pad insulating layer 115 may be formed of or include at least one of silicon oxide, silicon nitride, silicon carbon nitride, silicon oxynitride, or polymeric materials.

Second connection pads 160 may be disposed adjacent to the top surface of the substrate 110. The second connection pads 160 may be provided in the pad insulating layer 115. Each of the second connection pads 160 may be in contact with and electrically connected to a corresponding one of the through vias 150. The second connection pads 160 may include a conductive metal material. For example, the second connection pads 160 may be formed of or include at least one of copper (Cu), aluminum (Al), tungsten (W), or titanium (Ti).

A dummy pattern 170 may be provided on the top surface 120a of the insulating layer 120. The dummy pattern 170 may be disposed on a sidewall of the substrate 110. For example, in some example embodiments, the dummy pattern 170 may contact the top surface 120a of the insulating layer 120 and may contact the sidewall of the substrate 110. The dummy pattern 170 may cover at least a portion of the top surface 120a of the insulating layer 120. In detail, the dummy pattern 170 may be disposed on a protruding portion of the insulating layer 120 which is located outside the substrate 110. The dummy pattern 170 may be disposed on the top surface 120a of the insulating layer 120, which is not covered by the substrate 110. The dummy pattern 170 may be disposed on the stepwise portion ST. As an example, the dummy pattern 170 may have an upward convex shape. The dummy pattern 170 may include at least one of a conductive metal material, an insulating material, or a semiconductor material. For example, the dummy pattern 170 may be formed of or include at least one of copper (Cu), aluminum (Al), tungsten (W), titanium (Ti), silicon (Si), silicon oxide, or silicon nitride.

In the semiconductor device according to example embodiments illustrated in FIGS. 1-3, the dummy pattern 170 may be disposed on a top surface of the protruding portion of the insulating layer 120, which is located outside the substrate 110. Accordingly, the dummy pattern 170 may not be disposed on the top surface of the substrate 110, a top surface of the pad insulating layer 115, and/or the bottom surface 120b of the insulating layer 120.

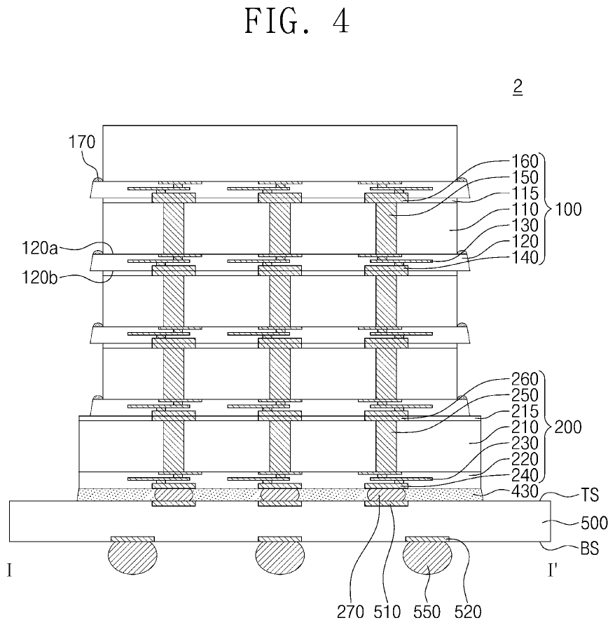

FIG. 4 is a sectional view, which is taken along the line I-I′ of FIG. 1 to illustrate a semiconductor package including a semiconductor device according to example embodiments. For concise description, a previously described element may be identified by the same reference number without repeating an overlapping description thereof.

Referring to FIGS. 1 and 4, a semiconductor package 2 may include the package substrate 500, the first semiconductor chip 100, and a second semiconductor chip 200.

The package substrate 500 may include the package substrate pads 510 and the terminal pads 520. The outer terminals 550 may be provided on the bottom surface BS of the package substrate 500. The package substrate 500 and the outer terminals 550 may be configured to have substantially the same features as those described with reference to FIGS. 1 and 2 and thus a repeated description thereof is omitted for conciseness.

The second semiconductor chip 200 may be provided on the package substrate 500 and may be mounted on the top surface TS of the package substrate 500. The second semiconductor chip 200 may include a base substrate 210 and a base insulating layer 220. The second semiconductor chip 200 may include a semiconductor chip that is of a different kind from the first semiconductor chip 100. The second semiconductor chip 200 may be, for example, a logic chip or a buffer chip and may be configured to have a different function from the semiconductor chip 100.

The base substrate 210 may be formed of or include at least one of semiconductor materials (e.g., silicon, germanium, or silicon-germanium). As an example, the base substrate 210 may be a chip level substrate. In example embodiments, the base substrate 210 may have a side surface that is substantially perpendicular to the top surface of the package substrate 500.

The base insulating layer 220 may be disposed on a bottom surface of the base substrate 210. The base insulating layer 220 may include an insulating material. For example, the base insulating layer 220 may be formed of or include at least one of silicon oxide, silicon nitride, or silicon oxynitride. The base insulating layer 220 may be composed of a single layer or may include a plurality of stacked layers. In some example embodiments, the base insulating layer 220 may have a side surface that is substantially perpendicular to the top surface of the package substrate 500. In example embodiments, the side surface of the base insulating layer 220 may be aligned to the side surface of the base substrate 210.

Interconnection patterns 230 may be provided in the base insulating layer 220. The interconnection patterns 230 may be provided to penetrate a portion of the base insulating layer 220. The interconnection patterns 230 may include a conductive metal material. For example, the interconnection patterns 230 may be formed of or include at least one of copper (Cu), aluminum (Al), tungsten (W), or titanium (Ti). The base insulating layer 220 may cover the interconnection patterns 230.

First chip pads 240 may be provided in the base insulating layer 220. The first chip pads 240 may be disposed adjacent to a bottom surface of the base insulating layer 220. The first chip pads 240 may be electrically connected to the interconnection patterns 230. The first chip pads 240 may be formed of or include at least one of conductive metal materials. For example, the first chip pads 240 may be formed of or include at least one of copper (Cu), aluminum (Al), tungsten (W), or titanium (Ti).

A chip via 250 may be provided in the base substrate 210. The chip via 250 may be provided to penetrate the base substrate 210. The chip via 250 may be electrically connected to the interconnection patterns 230. In example embodiments, a plurality of the chip vias 250 may be provided. The chip via 250 may include a conductive metal material. For example, the chip via 250 may be formed of or include at least one of copper (Cu), aluminum (Al), tungsten (W), or titanium (Ti). Although not shown, an insulating layer and/or a barrier layer may be further interposed between the chip via 250 and the base substrate 210.

A chip pad insulating layer 215 may be provided on a top surface of the base substrate 210. The chip pad insulating layer 215 may include an insulating material. For example, the chip pad insulating layer 215 may be formed of or include at least one of silicon oxide, silicon nitride, silicon carbon nitride, silicon oxynitride, or polymeric materials.

Second chip pads 260 may be disposed adjacent to the top surface of the base substrate 210. The second chip pads 260 may be provided in the chip pad insulating layer 215. Each of the second chip pads 260 may be electrically connected to a corresponding one of the chip vias 250. The second chip pads 260 may include a conductive metal material. For example, the second chip pads 260 may be formed of or include at least one of copper (Cu), aluminum (Al), tungsten (W), or titanium (Ti).

First connection terminals 270 may be provided on a bottom surface of the second semiconductor chip 200. The first connection terminals 270 may be interposed between the package substrate 500 and the second semiconductor chip 200. The first connection terminals 270 may be disposed on bottom surfaces of the first chip pads 240 and may be electrically connected to the first chip pads 240. The first connection terminals 270 may be coupled to the package substrate 500. The first connection terminals 270 may include at least one of, for example, solder balls, bumps, or pillars. The first connection terminals 270 may include a conductive metal material. For example, the first connection terminals 270 may be formed of or include at least one of tin (Sn), lead (Pb), silver (Ag), zinc (Zn), nickel (Ni), gold (Au), copper (Cu), aluminum (Al), or bismuth (Bi). Thus, the first connection terminals 270 may be electrically connected to the package substrate pads 510 of the package substrate 500.

A first under-fill layer 430 may be interposed between the package substrate 500 and the second semiconductor chip 200. The first under-fill layer 430 may be provided to fill a space between the first connection terminals 270 and to seal or encapsulate the first connection terminals 270. The first under-fill layer 430 may be formed of or include an insulating polymer (e.g., an epoxy-based polymer).

The first semiconductor chip 100 may be disposed on the second semiconductor chip 200. In example embodiments, a plurality of the first semiconductor chips 100 may be vertically stacked on the second semiconductor chip 200. The first semiconductor chips 100 may form a chip stack. In some example embodiments, the first semiconductor chips 100 may include high bandwidth memory (HBM) chips. For example, the first semiconductor chips 100 may include dynamic random-access memory (DRAM) chips. The first semiconductor chip 100 may include the substrate 110, the pad insulating layer 115, and the insulating layer 120. The dummy pattern 170 may be disposed on the top surface 120a of the protruding portion of the insulating layer 120 located outside the substrate 110. The first semiconductor chip 100 and the dummy pattern 170 may be configured to have substantially the same features as those described with reference to FIGS. 1 to 3 and thus a repeated description thereof is omitted for conciseness.

Adjacent ones of the first semiconductor chips 100 may be electrically connected to each other through the first and second connection pads 140 and 160. In the adjacent ones of the first semiconductor chips 100, the first connection pad 140 of an upper chip may be in direct contact with and electrically connected to the second connection pad 160 of a lower chip. Furthermore, in the adjacent ones of the first semiconductor chips 100, the insulating layer 120 of the upper chip may be in direct contact with the pad insulating layer 115 of the lower chip. The lowermost one of the first semiconductor chips 100 and the second semiconductor chip 200 may be electrically connected to each other through the first connection pad 140 and the second chip pad 260. The first connection pad 140 of the lowermost one of the first semiconductor chips 100 may be in direct contact with and electrically connected to the second chip pad 260 of the second semiconductor chip 200. The insulating layer 120 of the lowermost one of the first semiconductor chips 100 may be in direct contact with the chip pad insulating layer 215 of the second semiconductor chip 200. In example embodiments, the through via 150 and the second connection pad 160 may not be provided in the uppermost one of the first semiconductor chips 100. The number of the first semiconductor chips 100 is not limited to that in the example of FIG. 4 and may be variously changed.

In general, if a side surface of an insulating layer is aligned to a side surface of a substrate as in the related art, a dummy pattern may be disposed on a bottom surface of the insulating layer. In this case, due to the dummy pattern, it may be difficult to connect semiconductor devices, which are vertically stacked to be adjacent to each other in a vertical direction perpendicular to the top surface of the package substrate, through a pad bonding process; that is, the pad bonding process may suffer from low bonding efficiency.

By contrast, in the semiconductor device according to example embodiments, the dummy pattern 170 may be disposed on the protruding portion of the insulating layer 120 located outside the substrate 110. In this configuration, the dummy pattern 170 may not be disposed on the top surface of the substrate 110, the top surface of the pad insulating layer 115, and/or the bottom surface 120b of the insulating layer 120. Accordingly, in the semiconductor package including the semiconductor device, it may be possible to prevent a bonding failure from occurring between the first semiconductor chips 100, which are vertically stacked to be adjacent to each other in the vertical direction, or between the first and second connection pads 140 and 160 thereof. This configuration may make it possible to improve bonding efficiency in a process of bonding the first semiconductor chips 100, which are vertically stacked to be adjacent to each other in the vertical direction, and thereby to realize a semiconductor package with improved reliability.

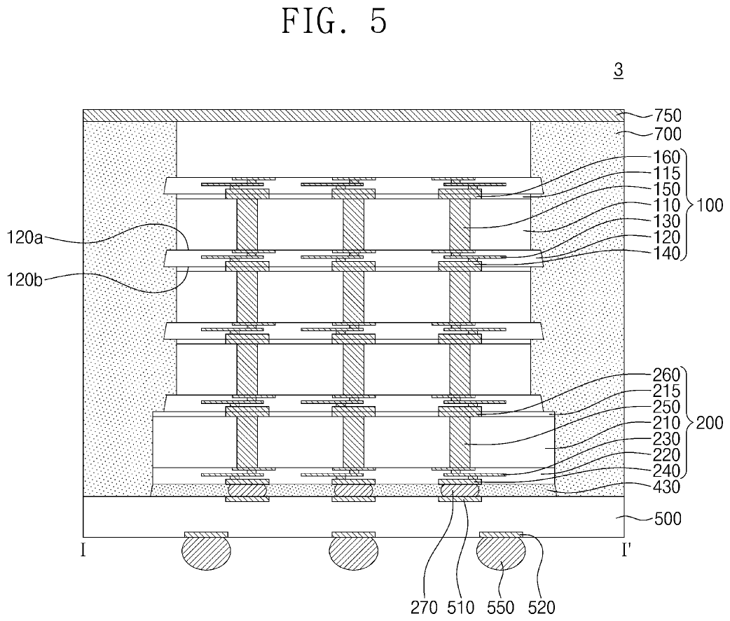

FIG. 5 is a sectional view, which is taken along the line I-I′ of FIG. 1 to illustrate a semiconductor package including a semiconductor device according to example embodiments. For concise description, a previously described element may be identified by the same reference number without repeating an overlapping description thereof for conciseness. It is noted that the dummy patterns 170 are not illustrated in FIG. 5.

Referring to FIGS. 1 and 5, a semiconductor package 3 may further include a mold layer 700 and a heat-dissipation structure 750, in addition to the package substrate 500, the first semiconductor chip 100, and the second semiconductor chip 200. The second semiconductor chip 200 may be mounted on the package substrate 500. The package substrate 500 may be configured to have substantially the same features as that described with reference to FIGS. 1 and 2, and the second semiconductor chip 200 may be configured to have substantially the same features as that described with reference to FIG. 4.

The first semiconductor chips 100 may be vertically stacked on the second semiconductor chip 200. The first semiconductor chip 100 may be configured to have substantially the same features as that described with reference to FIGS. 1 to 3. As described above, the dummy patterns 170 are not illustrated in FIG. 5. In some example embodiments, the dummy patterns 170 may be provided as illustrated in FIGS. 1-4. However, in other example embodiments, the dummy pattern 170 may not be provided on the top surface 120a of the insulating layer 120. For example, the dummy patterns 170 may be removed during a dicing process as described in more detail later.

The mold layer 700 may be provided on the package substrate 500. The mold layer 700 may cover the top surface of the package substrate 500, the second semiconductor chip 200, and the first semiconductor chips 100. In example embodiments, the mold layer 700 may be provided to expose a top surface of the uppermost one of the first semiconductor chips 100. However, example embodiments are not limited to this example, and unlike the illustrated structure, the mold layer 700 may be provided to cover the top surface of the uppermost one of the first semiconductor chips 100. In example embodiments, the mold layer 700 may be formed of or include an insulating polymer (e.g., an epoxy-based polymer).

The heat-dissipation structure 750 may be provided on the package substrate 500. The heat-dissipation structure 750 may be disposed on the top surface of the uppermost one of the first semiconductor chips 100. The heat-dissipation structure 750 may be in contact with the top surface of the uppermost one of the first semiconductor chips 100. The heat-dissipation structure 750 may include a heat slug or a heat sink. The heat-dissipation structure 750 may be formed of or include materials (e.g., metals) having high thermal conductivity.

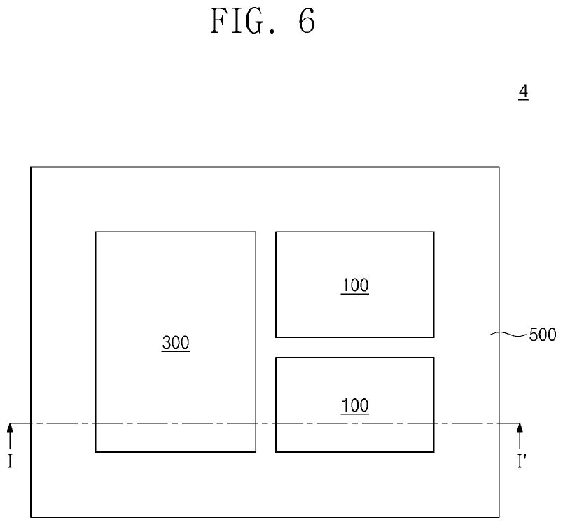

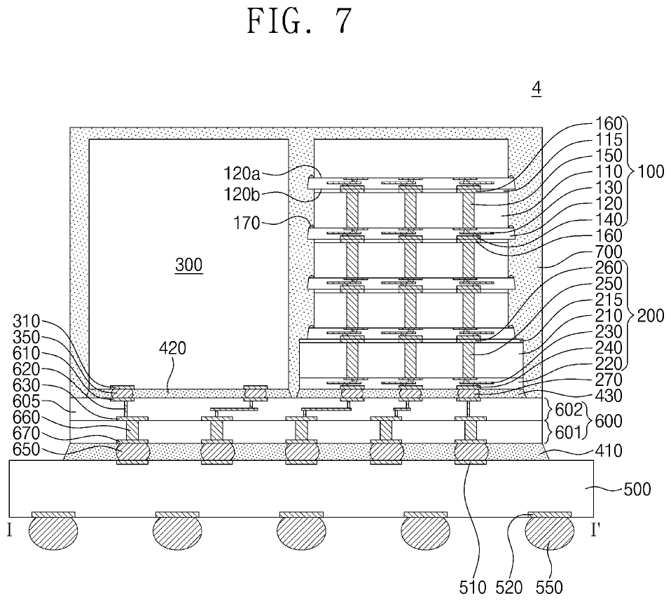

FIG. 6 is a plan view illustrating a semiconductor package including a semiconductor device according to example embodiments. FIG. 7 is a sectional view, which is taken along a line I-I′ of FIG. 6 to illustrate a semiconductor package including a semiconductor device according to example embodiments. For concise description, a previously described element may be identified by the same reference number without repeating an overlapping description thereof for conciseness.

Referring to FIGS. 6 and 7, a semiconductor package 4 may further include a third semiconductor chip 300 and an interposer substrate 600, in addition to the first semiconductor chip 100, the second semiconductor chip 200, and the package substrate 500.

The package substrate 500 may be provided. The package substrate 500 may include the package substrate pads 510 and the terminal pads 520. The outer terminals 550 may be provided on the bottom surface of the package substrate 500. The package substrate 500 and the outer terminals 550 have been described in more detail with reference to FIGS. 1 and 2 and thus a repeated description thereof is omitted for conciseness.

The interposer substrate 600 may be disposed on the package substrate 500. The interposer substrate 600 may include a substrate layer 601 and an interconnection layer 602 on the substrate layer 601.

The substrate layer 601 may include a plurality of penetration electrodes 660 and a plurality of lower pads 670. For example, the substrate layer 601 may be a silicon substrate. The penetration electrodes 660 may be provided in the substrate layer 601 to penetrate the substrate layer 601. Each of the penetration electrodes 660 may be electrically connected to a corresponding one of substrate interconnection lines 630, which will be described below. The lower pads 670 may be disposed adjacent to a bottom surface of the substrate layer 601. The lower pads 670 may be electrically connected to the penetration electrodes 660. The penetration electrodes 660 and the lower pads 670 may be formed of or include at least one of conductive metal materials (e.g., at least one of copper (Cu), aluminum (Al), tungsten (W), or titanium (Ti)).

The interconnection layer 602 may include upper pads 610, internal lines 620, the substrate interconnection lines 630, and an interconnection insulating layer 605. The interconnection insulating layer 605 may cover the upper pads 610, the internal lines 620, and the substrate interconnection lines 630. The upper pads 610 may be adjacent to a top surface of the interconnection layer 602, and the substrate interconnection lines 630 may be adjacent to a bottom surface of the interconnection layer 602. The upper pads 610 may be exposed to the outside of the interconnection layer 602 near the top surface of the interconnection layer 602. The internal lines 620 may be disposed in the interconnection insulating layer 605 and may be electrically connected to the upper pads 610 and the substrate interconnection lines 630. The upper pads 610, the internal lines 620, and the substrate interconnection lines 630 may include a conductive metal material and may be formed of or include at least one of copper (Cu), aluminum (Al), tungsten (W), or titanium (Ti).

Substrate bumps 650 may be interposed between the package substrate 500 and the interposer substrate 600. The package substrate 500 and the interposer substrate 600 may be electrically connected to each other through the substrate bumps 650. Each of the lower pads 670 may be electrically connected to a corresponding one of the package substrate pads 510 through a corresponding one of the substrate bumps 650. The substrate bumps 650 may include at least one of, for example, solder balls, bumps, or pillars. The substrate bumps 650 may include a conductive metal material. For example, the substrate bumps 650 may be formed of or include at least one of tin (Sn), lead (Pb), silver (Ag), zinc (Zn), nickel (Ni), gold (Au), copper (Cu), aluminum (Al), or bismuth (Bi). A pitch of the substrate bumps 650 may be smaller than a pitch of the outer terminals 550.

A substrate under-fill layer 410 may be interposed between the package substrate 500 and the interposer substrate 600. The substrate under-fill layer 410 may be provided to fill a space between the substrate bumps 650 and to seal or encapsulate the substrate bumps 650. In example embodiments, the substrate under-fill layer 410 may be formed of or include an insulating polymer (e.g., an epoxy-based polymer).

The second semiconductor chip 200 may be mounted on the interposer substrate 600. The first semiconductor chips 100 may be vertically stacked on the second semiconductor chip 200. Each of the first semiconductor chips 100 may include the substrate 110 and the insulating layer 120. The dummy pattern 170 may be disposed on the top surface 120a of the protruding portion of the insulating layer 120 located outside the substrate 110. The first semiconductor chip 100 and the dummy pattern 170 may be configured to have substantially the same features as those described with reference to FIGS. 1 to 3, and the second semiconductor chip 200 may be configured to have substantially the same features as that described with reference to FIG. 4 and thus repeated descriptions thereof are omitted for conciseness.

The third semiconductor chip 300 may be mounted on the interposer substrate 600. The third semiconductor chip 300 may be horizontally spaced apart from the first and second semiconductor chips 100 and 200. The third semiconductor chip 300 may be a semiconductor chip that is of a different kind from the first and second semiconductor chips 100 and 200. The third semiconductor chip 300 may include a logic chip, a buffer chip, or a system-on-chip (SOC). For example, the third semiconductor chip 300 may be an application specific integrated circuit (ASIC) chip or application processor (AP) chip. The ASIC chip may include an application specific integrated circuit (ASIC). The third semiconductor chip 300 may include a central processing unit (CPU) or a graphic processing unit (GPU).

The third semiconductor chip 300 may include third chip pads 310 that are adjacent to a bottom surface thereof. The third chip pads 310 may be electrically and respectively connected to the upper pads 610 of the interposer substrate 600. The third chip pads 310 may include a conductive metal material. For example, the third chip pads 310 may be formed of or include at least one of copper (Cu), aluminum (Al), tungsten (W), or titanium (Ti).

The first connection terminals 270 may be interposed between the interposer substrate 600 and the second semiconductor chip 200. The first connection terminals 270 may be disposed on the bottom surfaces of the first chip pads 240 and may be electrically connected to the interposer substrate 600. Each of the first chip pads 240 may be electrically connected to the upper pad 610 through a corresponding one of the first connection terminals 270. The interposer substrate 600 and the second semiconductor chip 200 may be electrically connected to each other through the first connection terminals 270.

Second connection terminals 350 may be provided on a bottom surface of the third semiconductor chip 300. The second connection terminals 350 may be interposed between the interposer substrate 600 and the third semiconductor chip 300. The second connection terminals 350 may be disposed on bottom surfaces of the third chip pads 310 and may be electrically connected to the interposer substrate 600. Each of the third chip pads 310 may be electrically connected to the upper pad 610 through a corresponding one of the second connection terminals 350. The interposer substrate 600 and the third semiconductor chip 300 may be electrically connected to each other through the second connection terminals 350. The second connection terminal 350 may include at least one of, for example, solder balls, bumps, or pillars. The second connection terminal 350 may include a conductive metal material. For example, the second connection terminal 350 may be formed of or include at least one of tin (Sn), lead (Pb), silver (Ag), zinc (Zn), nickel (Ni), gold (Au), copper (Cu), aluminum (Al), or bismuth (Bi).

The first under-fill layer 430 may be interposed between the interposer substrate 600 and the second semiconductor chip 200. The first under-fill layer 430 may be provided to fill a space between the first connection terminals 270 and to seal or encapsulate the first connection terminals 270. A second under-fill layer 420 may be interposed between the interposer substrate 600 and the third semiconductor chip 300. The second under-fill layer 420 may be provided to fill a space between the second connection terminals 350 and to seal or encapsulate the second connection terminals 350. The first under-fill layer 430 and the second under-fill layer 420 may be formed of or include an insulating polymer (e.g., an epoxy-based polymer).

The mold layer 700 may be provided on the interposer substrate 600. The mold layer 700 may cover a top surface of the interposer substrate 600, the first semiconductor chips 100, the second semiconductor chip 200, and the third semiconductor chip 300.

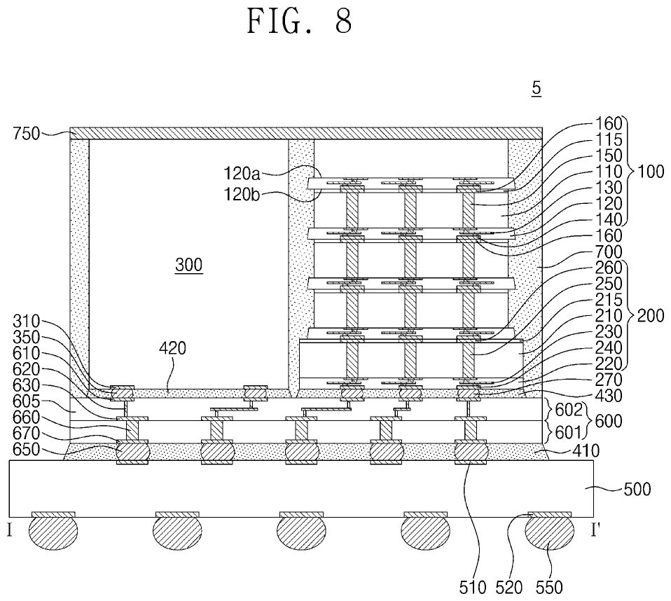

FIG. 8 is a sectional view, which is taken along a line I-I′ of FIG. 6 to illustrate a semiconductor package including a semiconductor device according to example embodiments. For concise description, a previously described element may be identified by the same reference number without repeating an overlapping description thereof for conciseness. It is noted that the dummy patterns 170 are not illustrated in FIG. 8.

Referring to FIGS. 6 and 8, a semiconductor package 5 may further include the heat-dissipation structure 750, in addition to the first semiconductor chips 100, the second semiconductor chip 200, the third semiconductor chip 300, the package substrate 500, and the interposer substrate 600. The interposer substrate 600 may be disposed on the package substrate 500. The second semiconductor chip 200 may be mounted on the interposer substrate 600. The first semiconductor chips 100 may be vertically stacked on the second semiconductor chip 200. The third semiconductor chip 300 may be mounted on the interposer substrate 600. The third semiconductor chip 300 may be horizontally spaced apart from the second semiconductor chip 200. The first semiconductor chips 100 and the package substrate 500 may be configured to have substantially the same features as those described with reference to FIGS. 1 to 3, the second semiconductor chip 200 may be configured to have substantially the same features as that described with reference to FIG. 4, and the third semiconductor chip 300 and the interposer substrate 600 may be configured to have substantially the same features as those described with reference to FIGS. 6 and 7 and thus a repeated description thereof is omitted for conciseness. As described above, the dummy patterns 170 are not illustrated in FIG. 8. In some example embodiments, the dummy patterns 170 may be provided as illustrated in FIGS. 1-5 and 7. However, in other example embodiments, the dummy pattern 170 may not be provided on the top surface 120a of the insulating layer 120 of the first semiconductor chip 100. For example, the dummy patterns 170 may be removed during a dicing process as described in more detail later.

The mold layer 700 may be provided on the interposer substrate 600 to cover the top surface of the interposer substrate 600, the first semiconductor chips 100, the second semiconductor chip 200, and the third semiconductor chip 300. The mold layer 700 may be provided to expose the top surface of the uppermost one of the first semiconductor chips 100.

The heat-dissipation structure 750 may be provided on the interposer substrate 600. The heat-dissipation structure 750 may be disposed on the top surface of the uppermost one of the first semiconductor chips 100 and a top surface of the third semiconductor chip 300. The heat-dissipation structure 750 may be in contact with at least one of the top surface of the uppermost one of the first semiconductor chips 100 and the top surface of the third semiconductor chip 300. The heat-dissipation structure 750 may include a heat slug or a heat sink. The heat-dissipation structure 750 may be formed of or include materials (e.g., metals) having high thermal conductivity.

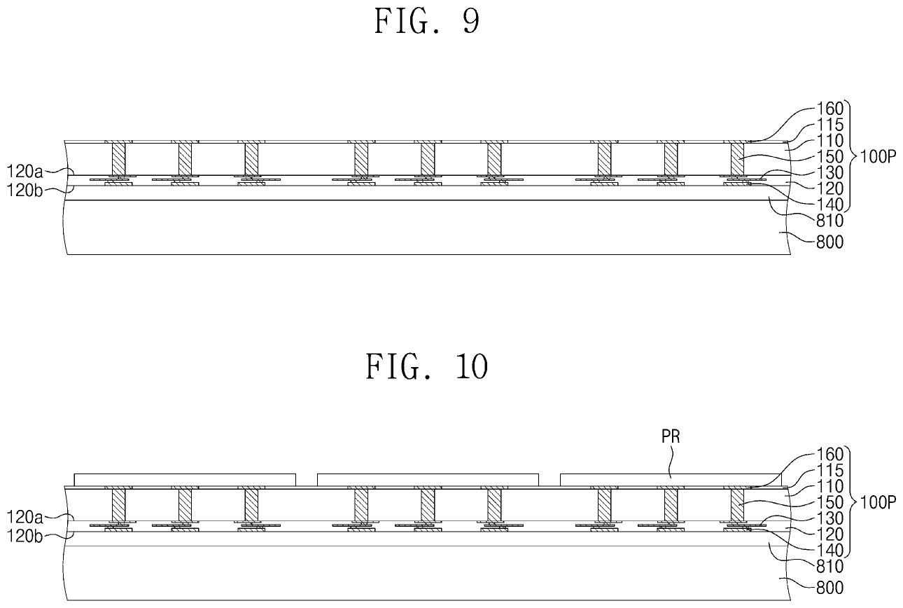

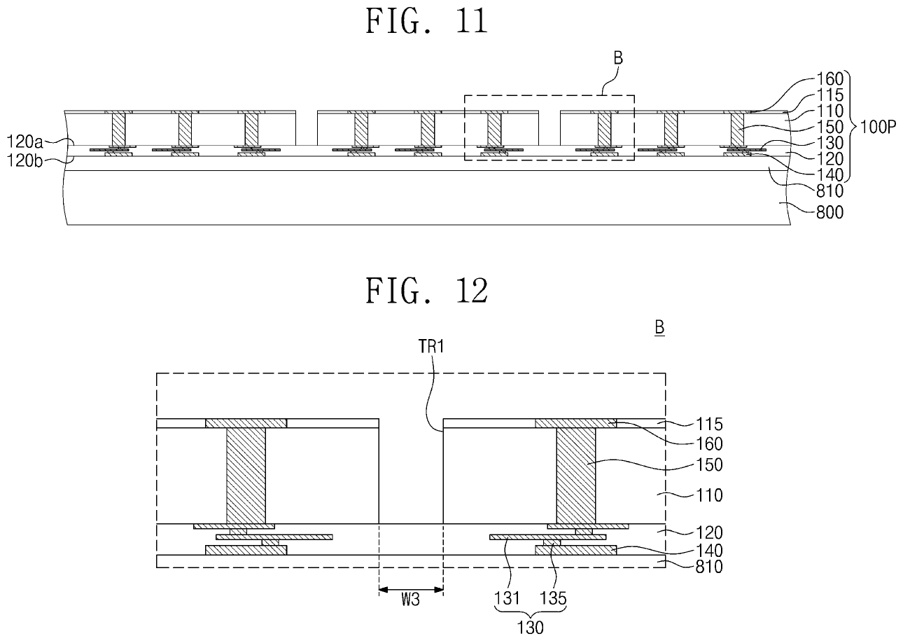

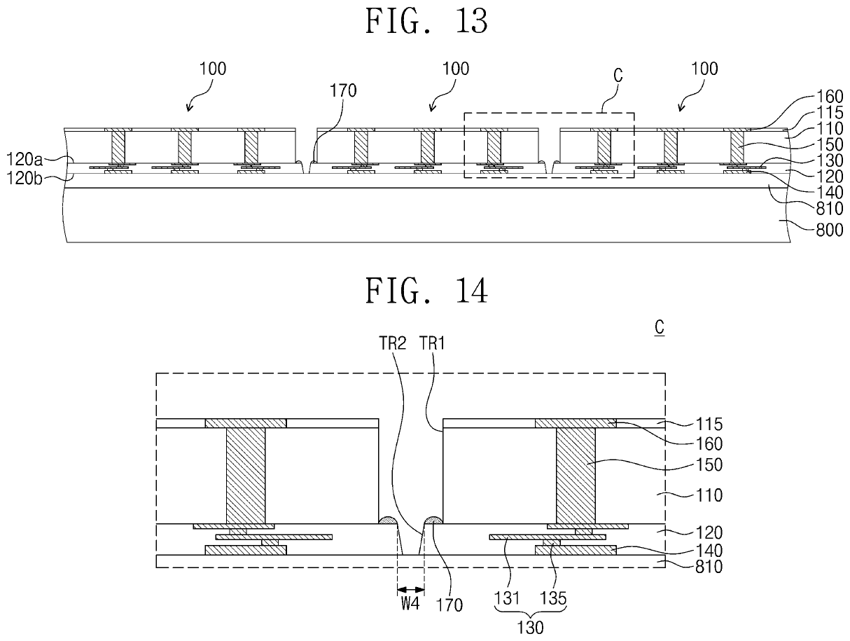

FIGS. 9, 10, 11, 13, 15, and 16 are sectional views illustrating a method of fabricating of a semiconductor package including a semiconductor device according to example embodiments. FIG. 12 is an enlarged sectional view illustrating a portion ‘B’ of FIG. 11. FIG. 14 is an enlarged sectional view illustrating a portion ‘C’ of FIG. 13. For concise description, a previously described element may be identified by the same reference number without repeating an overlapping description thereof for conciseness.

Referring to FIG. 9, a first carrier substrate 800 may be provided. An adhesive layer 810 may be formed on the first carrier substrate 800. For example, the adhesive layer 810 may be a polymer layer.

A preliminary semiconductor device 100P may be formed on the first carrier substrate 800. The preliminary semiconductor device 100P may be a wafer level substrate. The preliminary semiconductor device may include the substrate 110, the pad insulating layer 115, and the insulating layer 120. The substrate 110 may be, for example, a semiconductor wafer. The substrate 110 may be formed of or include at least one of semiconductor materials (e.g., at least one of silicon, germanium, or silicon germanium). The insulating layer 120 may be disposed on the bottom surface of the substrate 110. The insulating layer 120 may include an insulating material. For example, the insulating layer 120 may be formed of or include at least one of silicon oxide, silicon nitride, or silicon oxynitride. The pad insulating layer 115 may be disposed on the top surface of the substrate 110. The pad insulating layer 115 may include an insulating material. For example, the pad insulating layer 115 may be formed of or include at least one of silicon oxide, silicon nitride, silicon carbon nitride, silicon oxynitride, or polymeric materials.

The interconnection structures 130 may be provided in the insulating layer 120. The interconnection structures 130 may be formed of or include at least one of conductive metal materials. For example, the interconnection structures 130 may be formed of or include at least one of copper (Cu), aluminum (Al), tungsten (W), or titanium (Ti).

The first connection pads 140 may be provided in the insulating layer 120. The first connection pads 140 may be disposed adjacent to the bottom surface 120b of the insulating layer 120. The first connection pads 140 may include a conductive metal material. For example, the first connection pads 140 may be formed of or include at least one of copper (Cu), aluminum (Al), tungsten (W), or titanium (Ti).

The through via 150 may be provided in the substrate 110. The through via 150 may be provided to penetrate the substrate 110. The through via 150 may include a conductive metal material. For example, the through via 150 may be formed of or include at least one of copper (Cu), aluminum (Al), tungsten (W), or titanium (Ti).

The second connection pads 160 may be disposed adjacent to the top surface of the substrate 110. The second connection pads 160 may be provided in the pad insulating layer 115. The second connection pads 160 may include a conductive metal material. For example, the second connection pads 160 may be formed of or include at least one of copper (Cu), aluminum (Al), tungsten (W), or titanium (Ti).

Referring to FIG. 10, a photoresist pattern PR may be formed on the substrate 110. The photoresist pattern PR may cover a portion of the top surface of the pad insulating layer 115. The photoresist pattern PR may define a region, on which a dicing process will be performed in a subsequent step. For example, the photoresist pattern PR may be formed to expose the region of the preliminary semiconductor device 100P in which the dicing process is to be performed in the subsequent step.

Referring to FIGS. 11 and 12, a first dicing process may be performed on a top surface of the preliminary semiconductor device 100P. In example embodiments, the first dicing process may include cutting a portion of the preliminary semiconductor device 100P using plasma. A portion of the substrate 110 may be recessed by the first dicing process, and as a result, a first trench TR1 may be formed to expose a portion of the insulating layer 120. In example embodiments, the first trench TR1 may be formed to have width W3 ranging from about 80 μm to about 150 μm. The photoresist pattern PR may be removed after the first dicing process. However, in example embodiments, the photoresist pattern PR may be maintained until after performing a second dicing process to be described below, and then after performing the second dicing process, the photoresist pattern PR may be removed.

Referring to FIGS. 13 and 14, a second dicing process may be performed on the top surface of the preliminary semiconductor device 100P. In example embodiments, the second dicing process may include cutting the preliminary semiconductor device 100P using a laser beam or a blade. The insulating layer 120 may be recessed by the second dicing process, and as a result, a second trench TR2 may be formed to expose a portion of the adhesive layer 810. The formation of the second trench TR2 may include recessing a portion of a bottom surface of the first trench TR1. In example embodiments, the second trench TR2 may be formed to have a top width, which is larger than a bottom width of the second trench TR2, or to have an inclined inner side surface. A width W4 of the uppermost portion of the second trench TR2 may be smaller than the width W3 of the first trench TR1. For example, the width W4 of the uppermost portion of the second trench TR2 may range from about 20 μm to about 80 μm.

As a result of the second dicing process, the dummy pattern 170 may be formed on the bottom surface of the first trench TR1. For example, the dummy pattern 170 may be a burr generated by the second dicing process. The dummy pattern 170 may be formed on the top surface 120a of the insulating layer 120 exposed through the first trench TR1. In an embodiment, the dummy pattern 170 may include a residue material, which is produced from at least one of the insulating layer 120, the interconnection structure 130, the first connection pad 140, and the substrate 110 during the second dicing process and is deposited on the top surface 120a of the insulating layer 120. As described above, in some example embodiments, if the photoresist pattern PR was maintained while the second dicing process was performed, the photoresist pattern PR may be removed.

The preliminary semiconductor device 100P may be cut by the first and second dicing processes and may be divided into the first semiconductor chips 100. However, in some example embodiments, the dummy pattern 170 may be removed after the second dicing process, unlike the illustrated structure.

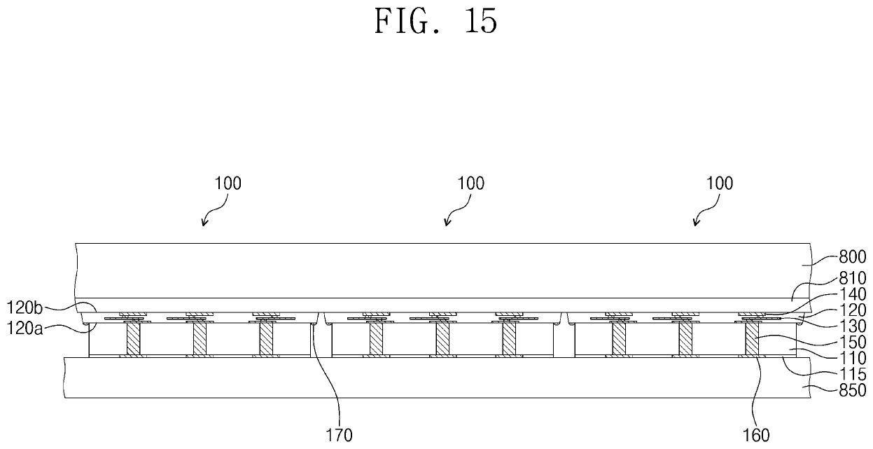

Referring to FIG. 15, a second carrier substrate 850 may be formed on the top surface of the pad insulating layer 115. The second carrier substrate 850 may cover the top surface of the pad insulating layer 115. The structure including the first semiconductor chips 100 and the second carrier substrate 850 may be inverted such that the first carrier substrate 800 is placed over the second carrier substrate 850.

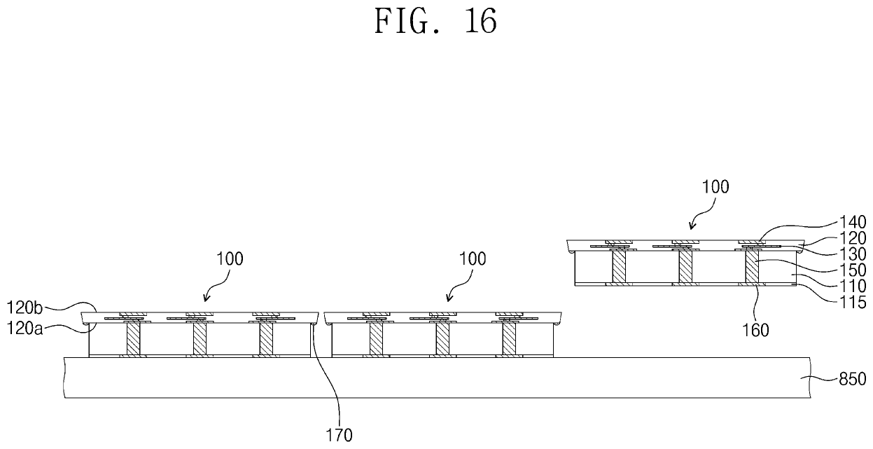

Referring to FIG. 16, the first carrier substrate 800 and the adhesive layer 810 may be removed. Because of the dicing process, the first semiconductor chips 100 may be separated or detached from the second carrier substrate 850. A semiconductor device according to an embodiment may be fabricated through the afore-described process.

Referring back to FIGS. 1 and 2, the package substrate 500 may be provided. The package substrate 500 may include the package substrate pads 510 and the terminal pads 520. The first semiconductor chip 100, which is detached from the second carrier substrate 850, may be mounted on the package substrate 500. The mounting of the first semiconductor chip 100 may include placing the first semiconductor chip 100 such that each of the first connection pads 140 is in contact with a corresponding one of the package substrate pads 510. A semiconductor package including the semiconductor device may be manufactured through the afore-described process.

According to various example embodiments, the first dicing process may be performed on the substrate 110 to form the first trench TR1, and then, the second dicing process may be performed to form the second trench TR2, which has a width smaller than the first trench TR1. As a result, the semiconductor device may be fabricated to include the dummy pattern 170, which is disposed on the protruding portion of the insulating layer 120 located outside the substrate 110. This structure means that it is possible to prevent a residue material, e.g., a burr, which is produced during the dicing process, from being deposited on the top surface of the substrate 110 or on the top surface of the pad insulating layer 115. Accordingly, in a subsequent packaging process, it may be possible to prevent a bonding failure from occurring between the first semiconductor chips 100, which are vertically stacked to be adjacent to each other in the vertical direction, or between the first and second connection pads 140 and 160 thereof. This structure may make it possible to improve bonding efficiency in a process of bonding the first semiconductor chips 100, which are vertically stacked to be adjacent to each other in the vertical direction, and thereby to realize a semiconductor package with improved reliability.

In a semiconductor device according to various example embodiments, a dummy pattern may be disposed on a top surface of an outward protruding portion of an insulating layer, which is located outside a substrate. Accordingly, in a semiconductor package including the semiconductor device, it may be possible to prevent a bonding failure from occurring between semiconductor chips, which are vertically stacked to be adjacent to each other in the vertical direction, or between connection pads thereof. This structure may make it possible to improve bonding efficiency in a process of bonding semiconductor chips, which are vertically stacked to be adjacent to each other in the vertical direction, and thereby to realize a semiconductor package with improved reliability.

While various example embodiments have been particularly shown and described, it will be understood by one of ordinary skill in the art that variations in form and detail may be made therein without departing from the spirit and scope of the attached claims.

What is claimed is:

1. A semiconductor device comprising:
a substrate;
an insulating layer on a bottom surface of the substrate, a portion of a top surface of the insulating layer that faces the substrate being exposed outside a side surface of the substrate;
a through via penetrating the substrate;
an interconnection structure in the insulating layer; and
a dummy pattern on the portion of the top surface of the insulating layer that is exposed by the substrate.

2. The semiconductor device of claim 1, wherein the dummy pattern includes a conductive metal material, and
wherein the conductive metal material includes at least one of copper, aluminum, tungsten, or titanium.

3. The semiconductor device of claim 1, wherein the dummy pattern includes an insulating material, and
wherein the insulating material includes at least one of silicon, silicon oxide, or silicon nitride.

4. The semiconductor device of claim 1, wherein the side surface of the substrate is misaligned to a side surface of the insulating layer.

5. The semiconductor device of claim 1, wherein an angle between a bottom surface of the insulating layer and a side surface of the insulating layer is equal to or greater than 20° and is smaller than 90°.

6. The semiconductor device of claim 5, wherein the side surface of the substrate is perpendicular to a top surface of the substrate.

7. The semiconductor device of claim 1, wherein a difference between a width of an uppermost portion of the insulating layer and a width of the substrate is from 10 μm to 130 μm.

8. The semiconductor device of claim 1, wherein a width of the insulating layer increases as a distance from a bottom surface of the insulating layer decreases.

9. The semiconductor device of claim 1, further comprising:
a plurality of first connection pads adjacent to a bottom surface of the insulating layer; and
a plurality of second connection pads adjacent to a top surface of the substrate.

10. A semiconductor device comprising:
a substrate;
an insulating layer on a bottom surface of the substrate;
a through via penetrating the substrate;
an interconnection structure in the insulating layer; and
a first connection pad adjacent to a bottom surface of the insulating layer,
wherein a portion of a top surface of the insulating layer is outside a side surface of the substrate, and
wherein an angle between the bottom surface and a side surface of the insulating layer is an acute angle.

11. The semiconductor device of claim 10, further comprising a dummy pattern disposed on the portion of the top surface of the insulating layer and the side surface of the substrate.

12. The semiconductor device of claim 11, wherein the dummy pattern has an upward convex shape.

13. The semiconductor device of claim 10, wherein a width of the substrate is smaller than a width of an uppermost portion of the insulating layer.

14. The semiconductor device of claim 10, wherein the substrate exposes the portion of the top surface of the insulating layer.

15. The semiconductor device of claim 10, wherein the first connection pad is electrically connected to the interconnection structure.

16. The semiconductor device of claim 10, further comprising:
a pad insulating layer on the substrate; and
a second connection pad in the pad insulating layer,
wherein the through via is in contact with the second connection pad.

17. A semiconductor package comprising:
a package substrate;
a first semiconductor chip on the package substrate; and
a plurality of outer terminals on a bottom surface of the package substrate,
wherein the first semiconductor chip comprises:
a substrate;
an insulating layer on a bottom surface of the substrate;
a through via penetrating the substrate;
an interconnection structure in the insulating layer, the interconnection structure comprising a conductive via penetrating a portion of the insulating layer, and a conductive pattern electrically connected to the conductive via;
a stepwise portion, which is provided by a portion of the insulating layer protruding outward from a side surface of the substrate; and
a dummy pattern disposed on the stepwise portion.

18. The semiconductor package of claim 17, further comprising:
a second semiconductor chip disposed between the package substrate and the first semiconductor chip; and
a plurality of third semiconductor chips stacked on the first semiconductor chip,
wherein the first semiconductor chip comprises an upper connection pad adjacent to a top surface thereof,
wherein a lowermost one of the plurality of third semiconductor chips comprises a lower connection pad adjacent to a bottom surface thereof, and
wherein the upper connection pad and the lower connection pad are in contact with each other.

19. The semiconductor package of claim 18, wherein the second semiconductor chip is of a different kind from the first semiconductor chip, and
wherein the plurality of third semiconductor chips are of a same kind as the first semiconductor chip.

20. The semiconductor package of claim 17, further comprising:
a second semiconductor chip disposed between the package substrate and the first semiconductor chip; and
a third semiconductor chip horizontally spaced apart from the second semiconductor chip,
wherein the third semiconductor chip is of a different kind from the first semiconductor chip.
